(19) United States
(12) Patent Application Publication
(10) Pub. No.: US 2012/0129293 A1
(43) Pub. Date: May 24, 2012

(54) METHODS OF MAKING AN UNSUPPORTED ARTICLE OF A SEMICONDUCTING MATERIAL USING THERMALLY ACTIVE MOLDS

(76) Inventors: Sergey Potapenko, Painted Post, NY (US); Balram Suman, Katy, TX (US); Lili Tian, Corning, NY (US); Alex Usenko, Painted Post, NY (US)

(21) Appl. No.: 13/300,829

(22) Filed: Nov. 21, 2011

Related U.S. Application Data
(60) Provisional application No. 61/417,012, filed on Nov. 24, 2010.

(51) Int. Cl. H01L 31/18; H01L 21/22

(52) U.S. Cl. 438/89; 438/542; 257/E21.135; 257/E31.032

(57) ABSTRACT

The invention relates to methods of making unsupported articles of semiconducting material using thermally active molds having an external surface temperature, T_{surface}, and a core temperature, T_{core}, whererin T_{surface}>T_{core}.

### FIELD

This application claims the benefit of priority under 35 U.S.C. §119 of U.S. Provisional Patent Application No. 61/417012 filed on Nov. 24, 2010 the content of which is relied upon and incorporated herein by reference in its entirety.

The disclosure relates to methods of making an unsupported article of a semiconducting material. In particular, the disclosure relates to methods comprising providing a mold with an external surface temperature T_{surface} and a core temperature T_{core}; providing a molten semiconducting material at a temperature Tₘₑₗₜ; immersing the mold in the molten semiconducting material for a period of time sufficient to form a solid layer of the semiconducting material over the external surface of the mold; withdrawing the mold with the solid layer of semiconducting material from the molten semiconducting material; and separating the solid layer of semiconducting material from the mold to form the unsupported article of semiconducting material. In various embodiments, T_{surface}>T_{core}, and Tₘₑₗₜ>T_{Core}. In further embodiments, Tₘₑₗₜ>T_{Core}. The disclosure further relates to methods for controlling the nucleation rate of silicon crystals on the mold when making an unsupported article of semiconducting material as described herein. The methods of the disclosure also relate to methods of increasing the efficiency of solar cells formed from articles of the semiconducting material. The methods according to the disclosure may also, in at least some embodiments, reduce material waste and/or increase the rate of production of the semiconducting material.

### BACKGROUND

Semiconducting materials find uses in many applications. For example, semiconducting materials can be used to manufacture switching elements, such as transistors in electronic devices, e.g., processors, formed on semiconductor wafers. As a further example, semiconducting materials are also used in solar cell manufacturing to convert solar radiation into electrical energy through the photovoltaic effect.

The semiconducting properties of a semiconducting material may depend on the crystal structure of the material. Notably, defects within the crystal structure of the semiconducting material may diminish the material's semiconducting properties.

The grain size, shape, and distribution often play an important part in the performance of the semiconducting devices where a larger and more uniform grain size is often desirable. For example, the efficiency of photovoltaic cells may be improved by increasing grain size and reducing the amount of defect in the grains.

For silicon-based photovoltaic cells, the silicon can, for example, be formed as an unsupported sheet or can be supported by forming the silicon on a substrate. Conventional methods for making unsupported and supported articles of semiconducting materials, such as silicon sheets, have several shortcomings.

Methods of making unsupported thin semiconducting material sheets, i.e., without an integral substrate, may be wasteful of the semiconducting material feedstock or very slow. Bulk growth of semiconducting materials, such as, for example, single-crystal and polycrystalline silicon ingots, require subsequent slicing of the ingot into thin sheets, leading to loss of material, e.g., approximately 50% kerf width from wire-sawing. Ribbon growth techniques overcome the loss of material due to slicing but may be slow, such as, for example, 1-2 cm/min for polycrystalline silicon ribbon growth technologies, and of lesser quality.

Supported semiconducting material sheets may be made less expensively, but the thin semiconducting material sheet is limited by the substrate on which it is made, and the substrate has to meet various process and application requirements, which may be conflicting.

Other useful methods for producing unsupported multicrystalline material are disclosed in U.S. Pat. No. 7,771,643, issued Aug. 10, 2010, titled “METHOD OF MAKING AN UNSUPPORTED ARTICLE OF SEMICONDUCTING MATERIAL BY CONTROLLED UNDERCOOLING,” the disclosure of which is hereby incorporated by reference.

Unsupported multicrystalline material made using a mold having a uniform temperature that is colder than that of the molten semiconducting material may, however, produce solar cells of lower efficiency than by other methods, such as ribbon processes.

Thus, there is a long-felt need in the industry for a method of making articles of a semiconducting material that may reduce material waste and/or increase the rate of production while also increasing the efficiency of solar cells formed from such articles of semiconducting material.

### SUMMARY

In accordance with the detailed description and various exemplary embodiments described herein, the disclosure relates to methods of making an unsupported article of a semiconducting material.

In various exemplary embodiments, the disclosure relates to methods comprising providing a mold with an external surface temperature T_{surface} and a core temperature T_{core}; providing a molten semiconducting material at a temperature Tₘₑₗₜ; immersing the mold in the molten semiconducting material for a period of time sufficient to form a solid layer of the semiconducting material over the external surface of the mold; withdrawing the mold with the solid layer of semiconducting material from the molten semiconducting material; and separating the solid layer of semiconducting material from the mold to form the unsupported article of semiconducting material. In various embodiments, T_{surface}>T_{core}, and Tₘₑₗₜ>T_{Core}. In further embodiments, Tₘₑₗₜ>T_{Core}.

In other exemplary embodiments, the disclosure relates to methods of controlling the nucleation rate and crystallization of silicon crystals on the mold when making an unsupported article of semiconducting material as described herein.

Other exemplary embodiments of the disclosure relate to methods of increasing the efficiency of solar cells formed from articles of the semiconducting material disclosed herein relative to that of semiconducting materials made by methods other than those disclosed herein. However, increase in efficiency may not be achieved in at least some embodiments of the disclosure.

The methods according to the disclosure may also, in at least some embodiments, reduce material waste and/or increase the rate of production of the semiconducting material. However, reduction of waste material and/or increase in the rate of production may not be achieved in at least some embodiments of the disclosure.

### BRIEF DESCRIPTION OF DRAWINGS

The accompanying drawings are included to provide a further understanding of the invention, and are incorporated in and constitute a part of this specification. The drawings are not intended to be restrictive of the invention as claimed, but rather are provided to illustrate exemplary embodiments of the invention and, together with the description, serve to explain the principles of the invention.

FIGS. 1A-C are a schematic illustration of an exemplary method of making an unsupported article of semiconducting material according to an embodiment of the disclosure;

FIGS. 2A-2C show exemplary molds used in accordance with exemplary methods of the disclosure;

FIG. 3 is a graph illustrating the initial temperature distribution inside the mold along cross-section A-A, shown in FIG. 2A, as function of position in the mold×(in cm) and temperature T (in degrees Celsius) at the time of immersion according to an embodiment of the disclosure;

FIG. 4 is a graph illustrating the relationship between the immersion time t (in seconds) and the thickness d (in microns) of a solid silicon layer formed on a mold according to an embodiment of the disclosure and in accordance with a method not within the scope of the disclosure;

FIG. 5 is a graph illustrating the relationship between the immersion time t (in seconds) and the thickness d (in microns) of a solid silicon layer formed on a mold according to an embodiment of the disclosure using three different core temperatures;

FIG. 6 is a graph illustrating the relationship between the immersion time t (in seconds) and the thickness d (in microns) of a solid silicon layer formed on a mold according to an embodiment of the disclosure using three different skin temperatures; and

FIG. 7 is a graph illustrating the relationship between the immersion time t (in seconds) and the thickness d (in microns) of a solid silicon layer formed on a mold according to an embodiment of the disclosure using molds of three different thicknesses.

### DETAILED DESCRIPTION

It is to be understood that both the foregoing general description and the following detailed description are exemplary and explanatory only and are not restrictive of the invention, as claimed. Other embodiments will be apparent to those skilled in the art from consideration of the specification and practice of the embodiments disclosed herein. It is intended that the specification and examples be considered as exemplary only, with the true scope and spirit of the invention being indicated by the claims.

As used herein the use of “the,” “a,” or “an” means “at least one,” and should not be limited to “only one” unless explicitly indicated to the contrary. Thus, for example, the use of “the semiconducting material” or “a semiconducting material” is intended to mean at least one semiconducting material.

The disclosure relates, in various embodiments, to methods of making an unsupported article of a semiconducting material. In particular, the disclosure relates to methods comprising providing a mold with an external surface temperature T_{surface} and a core temperature T_{core}; providing a molten semiconducting material at a temperature Tₘₑₗₜ; immersing the mold in the molten semiconducting material for a period of time sufficient to form a solid layer of the semiconducting material over the external surface of the mold; withdrawing the mold with the solid layer of semiconducting material from the molten semiconducting material; and separating the solid layer of semiconducting material from the mold to form the unsupported article of semiconducting material. In various embodiments, T_{surface}>T_{core}, and Tₘₑₗₜ>T_{Core}. In further embodiments, Tₘₑₗₜ>T_{Core}.

As used herein, the term “semiconducting material” includes materials that exhibit semiconducting properties. In various embodiments, the semiconducting material may be selected from silicon, germanium, tin, gallium arsenide, alloys thereof, and mixtures thereof. In at least one embodiment, the semiconducting material may be silicon. According to various embodiments, the semiconducting material may be pure (such as, for example, intrinsic or i-type silicon) or doped (such as, for example, silicon containing a n-type or p-type dopant, such as phosphorous or boron, respectively). In at least one embodiment of the disclosure, the semiconducting material comprises at least one dopant selected from boron, phosphorous, or aluminum (B, P, or Al). The amount of dopant present in the molten semiconducting material may be chosen based on the desired dopant concentration and distribution in the produced article of semiconducting material and may depend on the final use of the article, such as, for example, a photovoltaic cell. One skilled in the art will select the necessary temperature distribution based on the thermal properties of the material such as heat capacity, thermal conductivity and/or latent heat of fusion.

In at least one further embodiment, the semiconducting material may comprise at least one non-semiconducting element that may form a semiconducting alloy or compound with another element. For example, the semiconducting material may be selected from gallium arsenide (GaAs), aluminum nitride (AIN), and indium phosphide (InP).

In at least one further embodiment, the semiconducting material may have low contaminant levels. For example, the semiconducting material may comprise less than 1 ppm of iron, manganese, and chromium, and/or less than 1 ppb of vanadium, titanium, and zirconium. The semiconducting material may also comprise less than 10₁₅ atoms/cm₃ of nitrogen and/or less than 10₁₇ atoms/cm₃ of carbon. In at least one embodiment, the source of the semiconducting material may be photovoltaic-grade or purer silicon.

As used herein, the phrase “article of semiconducting material” includes any shape or form of semiconducting material made using the methods of the disclosure. Examples of such articles include articles that are smooth or textured; articles that are flat, curved, bent, or angled; and articles that are symmetric or asymmetric. Articles of semiconducting materials may comprise forms such as sheets or tubes.

As used herein, the term “unsupported” means that an article of semiconducting material is not integral with a mold. The unsupported article may be loosely connected to the mold while it is being formed, but the article of semiconducting material is separated from the mold after it is formed over the mold. The unsupported article may, however, be subsequently applied on a substrate for various applications, such as photovoltaic applications.

As used herein, the term “mold” means a physical structure that can influence the final shape of the article of semiconducting material. Molten or solidified semiconducting material need not actually physically contact a surface of the mold in the methods described herein, although contact may occur between a surface of the mold and the molten or solidified semiconducting material.

In at least one embodiment, the mold may be made of a material that is compatible with the molten semiconducting material. For example, the mold may comprise a material such that when the mold is exposed to the molten material, the mold does not react with the molten material in a manner that interferes with the methods disclosed herein, such as, for example, by forming a low-melting compound or solid solution. As a further example, the mold may comprise a material that does not melt or soften when the mold is heated via contact with the molten semiconducting material. As a further example, the mold may comprise a material that does not become too fluid to support the solid layer and/or does not separate from the solid layer when the mold is heated via contact with the molten semiconducting material. As a further example, the mold may comprise a material such that when the mold is heated via contact with the molten semiconducting material, the mold does not check, fracture, or explode due to, for example, large thermal stresses generated from uneven, rapid thermal expansion, or from trapped gases. As yet a further example, the mold may comprise a material that does not deleteriously contaminate either the solidified semiconducting material layer being formed on the mold or the molten semiconducting material residuum via breakage, spallation, dusting, and diffusion of vapor or liquid phases of solid components or evolved gases. In at least one embodiment, the mold may comprise a material selected from vitreous silica, graphite, silicon nitride, alumina, alumina-silica, and combinations thereof. In at least one embodiment of the disclosure, the mold is made of vitreous silica.

The mold may be in any form suitable for use in the disclosed methods. For example, in at least one embodiment, the mold may be in the form of a monolith or in the form of a laminated structure, such as, for example, a laminated monolith.

The mold may comprise a porous or non-porous body, optionally with at least one porous or non-porous coating. In at least one embodiment, the mold may also comprise a uniform or non-uniform composition, uniform or non-uniform porosity, or other uniform or non-uniform structural characteristic throughout the mold body. For example, in at least one embodiment, the mold may be comprised of at least two materials, such as one material comprising the core of the mold and another comprising the external surface of the mold. As another example, the mold may be in two pieces (comprised of the same or different materials), such as a core and an external surface layer separated by a gap.

According to at least one embodiment, the mold may also be in any shape suitable for use in the disclosed method. In at least one embodiment, the mold may have an external surface with particular characteristics to form articles having a broad range of shapes, curvatures, and/or textures. For example, the mold may comprise one or more flat surfaces or one or more curved surfaces, for example one or more convex or concave surfaces. For example, the one or more flat surfaces may be used to create an article in the shape of a rectangle, and the one or more convex or concave surfaces may be used to create an article in the shape of a lens or a tube.

According to at least one embodiment of the disclosure, the mold may be coated with particles, for example prior to being immersed or as the mold is immersed in the molten semiconducting material. In certain embodiments, a coating of particles may serve as a release agent, i.e., prevent the cast articles from sticking to the mold, and may allow crystals of the semiconducting material to grow uninterrupted, thereby resulting in larger grain size. In at least one embodiment, the mold may be coated with particles, for example inorganic particles. In at least one embodiment, the particles may be of high purity. According to at least one embodiment, the particles have an average size ranging from 10 nm to 2 μm. In at least one embodiment, the particles are nanoparticles having an average size of 100 nm or less, such as, for example, 30 nm or less. The particles may comprise any material suitable for use in the disclosed method. For example, in at least one embodiment, the particles may comprise silicon, silicon dioxide, silicon nitride, aluminum oxides, compounds of aluminum oxide, and/or glassy or crystalline compounds comprising aluminum and/or silicon, such as, for example, aluminum silicate.

As used herein, the term “external surface of the mold” means a surface of the mold that may be exposed to a molten semiconducting material upon immersion. For example, the interior surface of a tube-shaped mold may be an external surface if the interior surface can contact a molten semiconducting material when the mold is immersed.

As used herein, the term “temperature of the external surface of the mold,” “surface temperature,” and variations thereof mean the average temperature of the external surface of the mold at the point of entry into the molten semiconducting material.

As used herein, the term “core of the mold” means an internal region of the mold. In at least one embodiment, the core of the mold may be the internal center of the mold, e.g., the region or points equidistant from two opposing external surfaces of the mold. For example, the core of a cylindrical rod-shaped mold may be the center axis of the mold, running the length of the mold, perpendicular to the radius.

In various embodiments, the distance from the core of the mold to the external surface of the mold may range from about 0.05 cm to 0.5 cm, such as about 0.1 cm to 0.4 cm, for example about 0.1 cm or 0.2 cm.

As used herein, the term “temperature of the core of the mold,” “core temperature,” and variations thereof mean the average temperature of the core of the mold at the point of entry into the molten semiconducting material. The term core temperature is used to characterize the heat sink capacity of the mold. The temperature distribution in the mold will depend on the type of heating, the heating process, thermal properties of the mold, and the time elapsed since the heating/cooling preparation started.

It should be noted that the temperature distribution is created dynamically and therefore the thermal active mold should be used before the thermal conductivity in the mold will destroy the desired distribution. Furthermore, the process of creating the temperature distribution may continue during immersion of the mold into the melt.

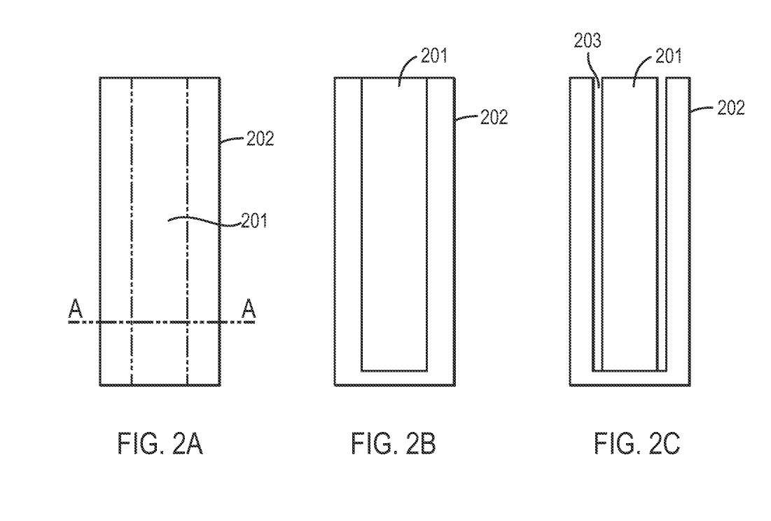

FIGS. 2A-C show exemplary molds that may be used in accordance with exemplary methods of the disclosure. FIG. 2A shows a single material mold made up of a single piece, comprising a core 201 and external surface 202. FIG. 2B shows a mold made up of two pieces of two different materials; one comprising the core 201, and the other comprising the external surface 202. FIG. 2C shows a mold made up of two pieces of two different materials separated by a gap 203; one material comprising the core 201, and the other comprising the external surface 202.

As used herein, the terms, “temperature of the molten semiconducting material,” “bulk temperature of the molten semiconducting material,” “melt temperature” and variations thereof mean the average temperature of the molten semiconducting material contained within the vessel. Local temperatures within the molten semiconducting material may vary at any point in time, such as, for example, areas of the molten semiconducting material close to the mold when the mold is immersed, or molten semiconducting material exposed to the atmospheric conditions at the top surface of the vessel. In various embodiments, the average temperature of the molten semiconducting material is substantially uniform despite any localized temperature variation.

As used herein, the phrase “form a solid layer of semiconducting material over an external surface of the mold” and variations thereof mean that semiconducting material from the molten semiconducting material solidifies (also referred to herein as freezing or crystallizing) on or near an external surface of the mold. Forming a solid layer of semiconducting material over an external surface of the mold may, in some embodiments, include solidifying semiconducting material on a layer of particles that coat the external surface of the mold. In various embodiments, due to the temperature difference between the mold and the molten semiconducting material, the semiconducting material may solidify before it physically contacts the surface of the mold. When the semiconducting material solidifies before it physically contacts the mold, the solidified semiconducting material may, in some embodiments, subsequently come into physical contact with the mold or with particles coating the mold. The semiconducting material may, in some embodiments, also solidify after physically contacting the external surface of the mold, or particles coating the surface of the mold, if present.

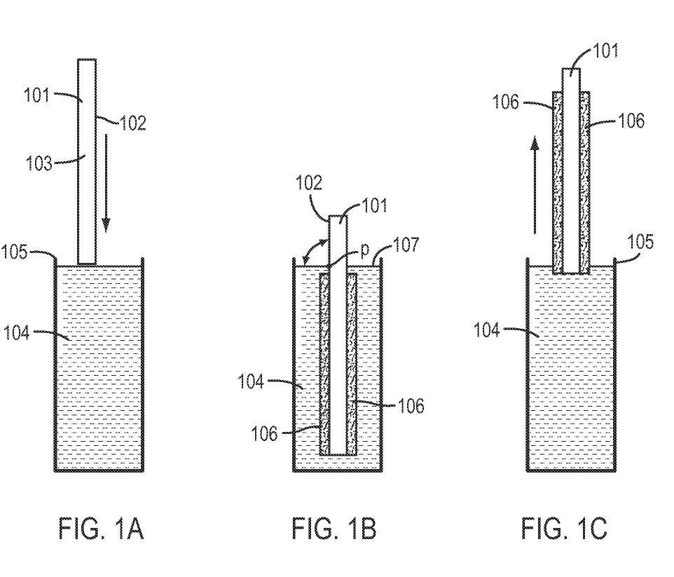

FIG. 1 illustrates an exemplary method of making an unsupported article of a semiconducting material. The exemplary method is an exocasting process, in which the article is casted on a surface, such as an external surface, of a mold, rather than only filling a mold cavity. In the exemplary method shown in FIG. 1A, the mold 101 is provided having an external surface 102 with a desired size (surface area), shape, and surface texture/pattern and a core 103. The surface area, shape, and surface texture/pattern of the external surface 102 of the mold 101 may determine the size, shape, and surface texture/pattern of the cast article. One of ordinary skill in the art would recognize that the size, shape, and surface texture/pattern of the external surface 102 of the mold 101 can be selected based on, for example, the desired properties and features of the cast article.

Molten semiconducting material 104 such as, for example, molten silicon, may in at least one embodiment be provided by melting silicon in a vessel, such as a crucible 105. In at least one embodiment the vessel 105, which holds the molten semiconducting material 104, may not react with the molten material 104 and/or may not contaminate the molten material 104, as described above for the mold 101. In at least one embodiment, the vessel 105 may be made from a material selected from vitreous silica, graphite, and silicon nitride. In at least one embodiment, vessel 105 is made of vitreous silica.

In at least one exemplary embodiment of the disclosure, the external surface of the mold 102 may be brought to a temperature, T_{Surface}, which is higher than that of the core, T_{Core}, in a low oxygen or reducing atmosphere using any suitable heating device or method. Examples of suitable heating devices and methods include heating elements, such as resistive or inductive heating elements, coherent light sources, and a flame heat source. One skilled in the art would recognize that the choice of heating device or method and the heating process may be made based on factors such as, for example, the environment in which the mold is heated, the material of the mold, the thickness of the mold, and/or the desired level of contaminants in the final article produced.

In at least one exemplary embodiment of the disclosure, the core of the mold 103 may be brought to a temperature, T_{Core}, in a low oxygen or reducing atmosphere using any suitable heating device or method. As described above, suitable heating devices and methods include heating elements, such as resistive or inductive heating elements, and a flame heat source. As also described above, one skilled in the art would recognize that the choice of heating device or method may be made based on factors such as, for example, the environment in which the mold is heated, the material of the mold, the thickness of the mold, and/or the desired level of contaminants in the final article produced.

In at least one exemplary embodiment of the disclosure, the molten semiconducting material 104 may be brought to a bulk temperature, T_{Melt}, in a low oxygen or reducing atmosphere using any suitable heating device or method. As described above, suitable heating devices and methods include heating elements and a flame heat source. As also described above, one skilled in the art would recognize that the choice of a heat source depends on several factors such as, for example, the capacity of the vessel containing the molten semiconducting material, the size/thickness of the vessel, and/or the atmosphere surrounding the vessel.

In various embodiments, the bulk temperature of the molten semiconducting material, T_{Melt}, may be the melting temperature of the semiconducting material or may be a higher temperature. In at least one exemplary embodiment where the semiconducting material comprises silicon, the bulk temperature of the molten silicon, T_{Melt}, may range from 1412° C. to 1550° C., such as, for example, from 1450° C. to 1490° C., such as 1460° C.

Prior to immersion, the temperature of the external surface of the mold, T_{Surface}, may be greater than, less than, or about equal to the bulk temperature of the molten semiconducting material, T_{Melt}.

In at least one embodiment, the external surface of the mold, T_{Surface}, may be about equal to or less than the bulk temperature of the molten semiconducting material, T_{Melt}. In further embodiments, the temperature of the external surface of the mold, T_{Surface}, may be within a difference of about 10° C. to 700° C. to that of the molten semiconducting material, T_{Melt}, for example about 100° C. to 400° C.

In at least one exemplary embodiment where the semiconducting material comprises silicon, the temperature of the external surface of the mold, T_{Surface}, may be 1450° C. or less, such as, for example, from 1450° C. to 50° C., 1450° C. to 500° C., or 1400 ° C. to 1200° C., such as 1300° C. In at least one embodiment, the temperature of the external surface of the mold, T_{Surface}, may, for example, be chosen such that the mold 101 is able to cool the molten material adjacent to the surface of mold 102 to the solidifying/freezing point of the semiconducting material 104, and to remove sufficient heat from the semiconducting material 104 to freeze it.

In at least one embodiment, the temperature of the core of the mold, T_{Core}, is less than the bulk temperature of the molten semiconducting material, T_{Melt}. The core temperature may, for example, be chosen so that the mold 101 is able to cool the molten material adjacent the surface of mold 102 to the solidifying point of the semiconducting material 104, and to remove sufficient heat from the semiconducting material 104 to solidify it. In at least one exemplary embodiment where the semiconducting material comprises silicon, the temperature of the core of the mold, T_{Core}, may range from −50° C. to 1400° C. prior to immersion in the molten semiconducting material. For example, in at least one embodiment, the temperature of the core of the mold, T_{Core}, may range from 50° C. to 200° C. prior to immersion in the molten semiconducting material, such as 100° C.

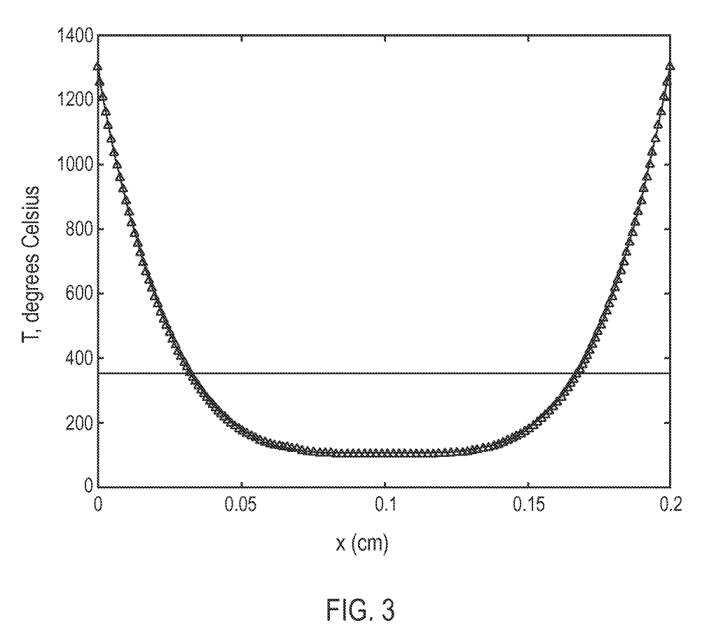

FIG. 3 is a graph illustrating a temperature distribution in the mold at the time of immersion according to an exemplary embodiment of the disclosure. The horizontal axis in FIG. 3 is the position across the thickness of the mold (in cm), shown on the x-axis, and the temperature (in degrees Celsius) at those positions is shown on the vertical y-axis. The temperature of the external surface of the mold, T_{Surface} , is shown at thickness 0 and 0.2 cm as about 1300° C., and the temperature of the core of the mold, T_{Core}, is shown at thickness 0.1 cm as about 100° C.

The temperature distribution in the mold will depend on, among other things, the type of heating, the heating process, thermal properties of the mold, and the time elapsed since the heating/cooling preparation started. It should be noted that the temperature distribution is created dynamically and therefore the thermal active mold should be used before the thermal conductivity in the mold will destroy the desired distribution. Furthermore, the process of creating the temperature distribution may continue during immersion of the mold into the melt.

In various embodiments, the temperature of the mold core 103 keeps driving down the temperature of the external mold surface 102 after it is submerged in the molten material, and the temperature difference between the mold surface 102 and molten semiconducting material 104 may drive the process. In at least one embodiment, the temperature difference may be sufficient to solidify the semiconductor material in a relatively short time, such as within a range of 1 second to 50 seconds, for example 2 to 20 seconds.

Returning to FIG. 1B, the mold 101 may be immersed in the molten semiconducting material 104 at a predetermined rate, and optionally in a low oxygen or reducing atmosphere. The mold 101 may be immersed in molten semiconducting material 104 at any immersion angle θ, where immersion angle θ is the angle between the surface 107 of molten semiconducting material 104 and the external surface 102 of the mold 101 at the point P that first contacts the surface 107 of molten semiconducting material 104 as shown in FIG. 1B. The angle at which the external surface 102 of the mold 101 contacts molten semiconducting material 104 may vary as the mold 101 is immersed in molten semiconducting material 104. By way of example only, in one embodiment molten semiconducting material could contact a mold having a spherical external surface at an infinite number of angles as it is immersed, although the immersion angle θ would be 0° as the initial contact point would be parallel to the surface 107 of molten semiconducting material 104. In various exemplary embodiments, the mold 101 my be moved in a in a direction following or parallel to the orientation of the external surface 102 or may be moved in a direction that does not follow the orientation of the external surface 102. In further exemplary embodiments, the mold 101 may be moved in a direction parallel to the surface 107 of molten semiconducting material 104 as the mold 101 is immersed in a direction perpendicular to the surface 107 of molten semiconducting material 104. One skilled in the art would also recognize that the local immersion angle, that is the immersion angle at any finite location at the point P of first contact may also vary due to the surface properties (such as, for example, porosity or height variations) and the wetting angle of the material comprising the mold.

In a further exemplary embodiment, the external surface 102 of the mold 101 may be substantially perpendicular to the surface 107 of the molten semiconducting material 104, i.e., the immersion angle is approximately 90°. In a further embodiment, the external surface 102 of the mold 101 need not be perpendicular to the surface 107 of molten semiconducting material 104. By way of example, the external surface 102 of the mold 101 may be immersed in the molten semiconducting material 104 at an immersion angle ranging from 0° to 180°, such as from 0° to 90°, from 0° to 30°, from 60° to 90°, or at an immersion angle of 45°.

In at least one embodiment of the disclosure, immersion of the mold may be accomplished using any suitable technique, and may be accomplished by immersing the mold from above the molten semiconducting material or from the side or bottom of the molten semiconducting material.

When a mold having an core temperature, T_{Core}, less than that of the molten semiconducting material, T_{Melt}, is dipped into the melt, the liquid adjacent to the mold starts to solidify and the average solidification front initially moves into the melt in a direction close to normal to the surface of the mold. If the mold is dipped for long enough time, when the heat sink provided by the mold is depleted, the solidified semiconducting film starts to remelt at the surface contacting the melt. The mold has to be removed from the melt after a predetermined time corresponding to the desired thickness of the layer of semiconducting material.

Due to the high value of the latent heat required to solidify semiconducting materials such as silicon, the mold may need to have significant thermal mass and, therefore, low core temperature to provide a desirable thickness of semiconducting layer. On the other hand, at a high undercooling, such as that of an external surface temperature, T_{Surface}, significantly less than the melt temperature, T_{Melt}, large amount of semiconducting material nuclei form, which leads to small grain microstructure. Moreover at high initial undercooling, the propagation of the grain growth may become unstable and introduce additional defects. Thus, in order to obtain less defective semiconducting articles, i.e., those having larger grains of semiconducting material and fewer defects, the excessive overcooling should be avoided, especially in the beginning of the crystallization phase.

Thus, in order to obtain semiconducting articles capable of making more efficient solar cells, i.e., those having larger grains of semiconducting material and fewer defects, excessive overcooling should be avoided, especially in the beginning of the crystallization phase.

Elevating the temperature of the external surface of the mold, T_{Surface}, above the temperature of the core of the mold, T_{Mold}, and closer to the temperature of the molten semiconducting material, T_{Melt}, may minimize or avoid forming large amount of small grains and at the same time provide sufficient thermal mass to produce stable crystals of the semiconducting material. Other positive factor of the elevated external surface temperature is providing more stable propagation of nuclei crystallization front and therefore less defectiveness of the solidified semi conducting layer. As solidification front propagates near perpendicularly to mold surface, eventual silicon sheets have grain boundaries preferentially oriented perpendicularly to the sheet surfaces. This grain orientation is beneficial for high efficiency of solar cells.

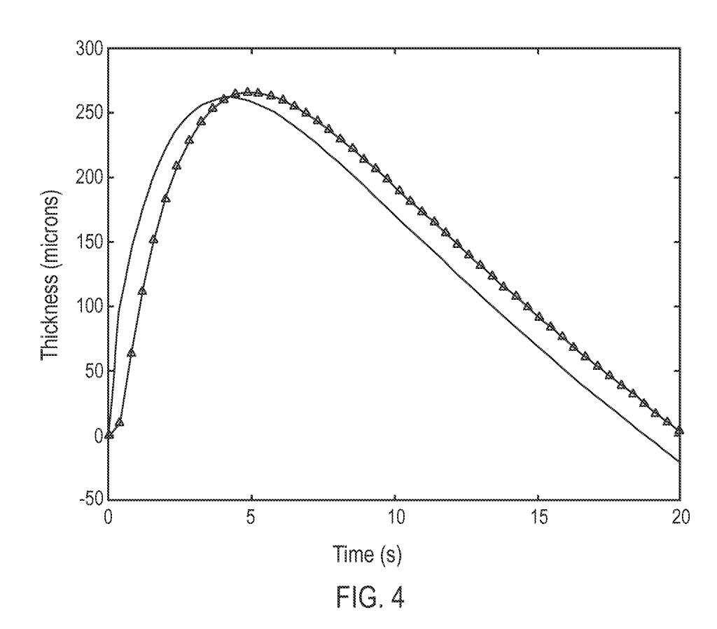

FIG. 4 is a graph illustrating the relationship between the immersion time (in seconds) (x-axis) and the thickness (in microns) of a solidified silicon layer formed on a mold (y-axis) according to an embodiment of the disclosure, illustrated by triangles, and in accordance with a method not within the scope of the disclosure, i.e., using uniform heating of the mold, illustrated by the solid line. As can be seen from the graph, both molds achieve layers of semiconductor material of similar maximum thickness; however, the mold in accordance with the present disclosure, i.e., having graduated temperature, has significantly less initial growth, which will result in lower nucleation rate and less instability when the grains expand along the silicon sheet.

In at least one embodiment, mold 101 may be immersed in the molten semiconducting material 104 for a period of time sufficient to allow a layer of the semiconducting material to sufficiently solidify on a surface 102 of the mold 101. In at least one embodiment, the semiconducting material is sufficiently solidified when enough semiconducting material has solidified such that the mold can be withdrawn from the molten semiconducting material and the layer of semiconducting material 106 will be withdrawn with the mold. By way of example only, the mold 101 may be immersed in the molten semiconducting material 104 for up to 30 seconds or more depending on the thickness of the mold 101, such as up to 10 seconds. In at least one embodiment, the mold 101 may be immersed from 0.5 seconds to 30 seconds. By way of example, the mold 101 may be immersed in the molten semiconducting material 104 for 1 second to 10 seconds. The immersion time may be varied appropriately based on parameters known to those of skill in the art, such as, for example, the thickness of the mold, the temperatures and heat transfer properties of the mold and the molten semiconducting material, and the desired thickness of the formed article of semiconducting material. Thus, the appropriate immersion time could easily be determined by one skilled in the art.

Returning to FIG. 1C, after immersion, the mold 101 with a layer of semiconducting material 106 may be withdrawn from the vessel 105. In at least one embodiment, the mold 101 with a layer of semiconducting material 106 may be cooled after it is removed from the vessel 105, either actively such as by convective cooling, or by allowing the temperature of the layer of semiconducting material 106 to come to room temperature.

After the mold is removed from the vessel and sufficiently cooled, the solid layer of semiconducting material may be removed or separated from the mold by any method known to those of skill in the art. In at least one embodiment, the layer of semiconducting material may be sufficiently cooled when it may be separated or removed from the mold without breaking or deforming. In at least one embodiment, the layer of semiconducting material may be separated or removed from the mold by differential expansion and/or mechanical assistance.

In various embodiments, oxygen contamination may optionally be mitigated or substantially mitigated, such as by melting the semiconducting material and casting the article in a low-oxygen environment, such as, for example, a dry mixture of hydrogen (<1 ppm of water) and an inert gas such as argon, krypton or xenon. In at least one exemplary embodiment, the atmosphere may be selected from an Ar/1.0 wt % H₂ mixture or Ar/2.5 wt % H₂ mixture.

In at least one embodiment of the disclosure, a rectangular silica sheet 156 mm×156 mm×0.2 mm with a handle is used as a mold. A robot may hold the handle of the silica sheet at an initial position above a crucible with molten silicon. A linear light source near the crucible top may project a plane light beam below the mold in its initial position and above or near the line where the mold enters the melt. The light beam may heat the surface of the mold to a temperature about 1400° C. as it moves to enter the molten silicon, which may be at a temperature of about 1800° C. While the robot arm moves the mold to dip it into the silicon, the mold may intersect the light beam, and its surface be heated. The moving speed of mold and relative position of mold, light beam, and melt surface are designed in such way that the time between heating by light and touching the silicon surface by mold is short enough that the external surface of the mold reaches the desired temperature, while the core of the mold remains colder, as a lower set temperature, such as 100° C. The mold may be dipped into the silicon melt and held for a desired time. Then the robot may move the mold up, retrieving the mold with a solidified silicon sheet on it. The robot may move the mold with the sheet away from the crucible, where it cools and is delaminated from the silica mold. The separated silicon sheet may then be further used as a substrate for making solar cells.

In various embodiments of the disclosure, a number of process parameters may be varied, including but not limited to: (1) the composition, density, heat capacity, thermal conductivity, thermal diffusivity, and thickness of the mold; (2) the external surface temperature of the mold, T_{Surface}, at which it is provided prior to immersion in the molten semiconducting material; (3) core temperature of the mold, T_{Core}, at which it is provided prior to immersion in the molten semiconducting material; (4) the rate at which mold is immersed into the molten semiconducting material; (5) the length of time that the mold is immersed in the molten semiconducting material; (6) the rate at which mold having the layer of semiconducting material is removed from the molten material; and (7) cooling of the solidified semiconducting material.

In at least one embodiment, the thermophysical properties of the material of the mold and the thickness of the mold may combine to determine the capacity of the mold to extract heat from the molten material in contact with the external surface of mold causing the semiconducting material to solidify, as well as the rate at which the heat may be transferred. As discussed above, it is believed that the rate at which heat is extracted from the solid layer of semiconducting material over the external surface of the mold may affect the grain size of the solid semiconducting material layer. The melt overcooling created by the mold provides a driving force for the liquid-to-solid phase transformation, while the heat transfer properties of the mold may define the rate at which the heat can be removed.

In at least one embodiment, the temperature of the external surface of the mold, T_{Surface}, the temperature of the core of the mold, T_{Core}, and the bulk temperature of the molten semiconducting material, T_{Melt}, are the only temperature parameters that are controlled (e.g., the temperature of the mold changes upon immersion in the molten semiconducting material while the temperature of the bulk molten semiconducting material is maintained at a constant temperature).

In at least one embodiment of the disclosure, the temperature of the external surface of the mold, T_{Surface}, and the temperature of the core of the mold, T_{Core}, are not controlled after the mold is immersed in the molten semiconducting material and, thus, is only altered by the temperature of the molten semiconducting material. The temperature of the molten semiconducting material, T_{Melt}, may alter the temperature of external surface and core of the mold through radiation, convection, or conduction. Radiative heating of mold may occur, for example, when the mold is above molten semiconducting material. The mold may be convectively heated by molten semiconducting material when fumes above molten semiconducting material pass over the surface of the mold or during immersion of mold in the molten semiconducting material. Heating of the mold by conduction may occur, for example, while the mold is immersed in molten semiconducting material.

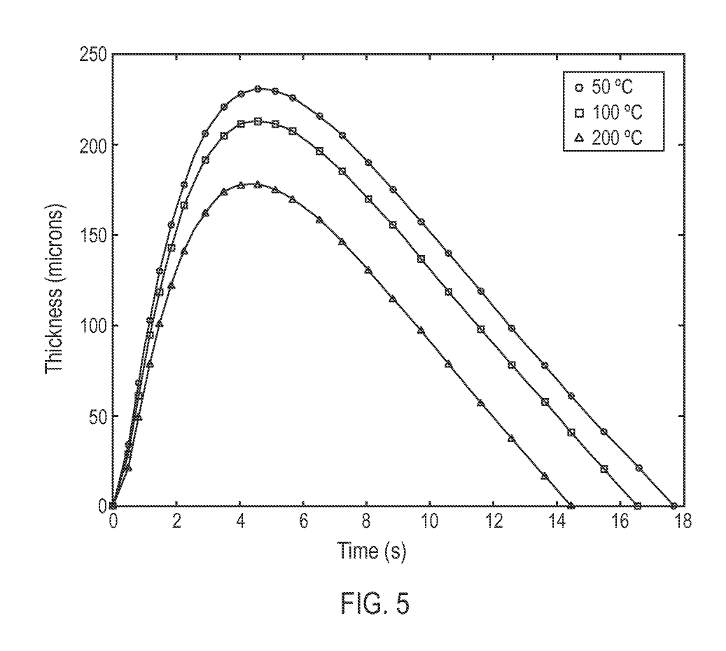

FIG. 5 shows an graphical representation of an exemplary theoretical calculation illustrating the thickness of a solidified silicon layer that may be achieved over time using molds having various mold core temperatures, T_{Core}, at the time of immersion corresponding to core temperature of 50° C., 100° C., and 200° C., as illustrated by circles, squares, and triangles, respectively. In the calculations, it was assumed that the mold is made of 100% dense (i.e., non-porous) vitreous silica and was 0.2 cm thick, that the external surface temperature of the mold was 1200° C. at the time of immersion, and that the molten silicon is maintained at 1470° C. during immersion of the mold in the molten silicon. As shown in the graph, a lower core temperature produces a thicker layer of semiconducting material, and a higher core temperature produces a lesser initial growth rate.

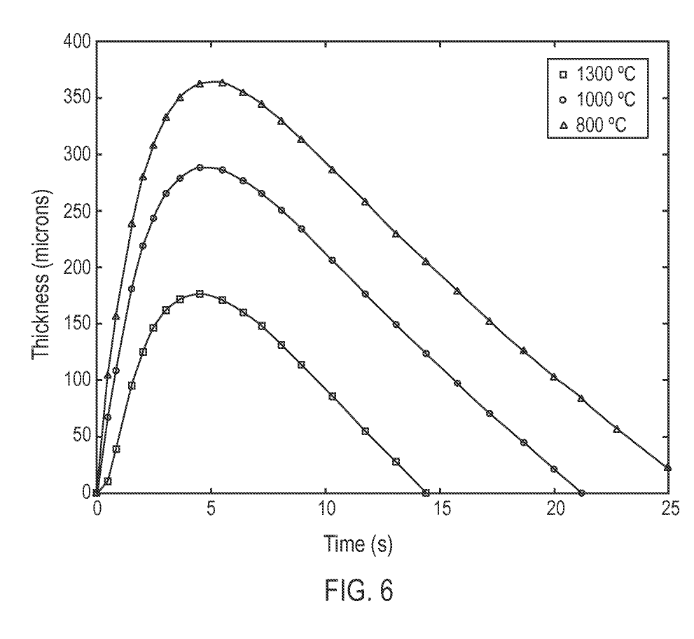

FIG. 6 shows an graphical representation of an exemplary theoretical calculation illustrating the thickness of a solidified silicon layer that may be achieved over time using molds having various external surface temperatures, T_{Surface}, at the time of immersion corresponding to an external surface temperature of 1300° C., 1000° C., and 800° C., as illustrated by squares, circles, and triangles, respectively. In the calculations, it was assumed that the mold is made of 100% dense (i.e., nonporous) vitreous silica and was 0.2 cm thick, that the temperature of the mold core was 100° C. at the time of immersion, and that the molten silicon is maintained at 1470° C. during immersion of the mold in the molten silicon. As shown in the graph, a lower external surface temperature produces a thicker layer of semiconducting material, and a higher external surface temperature produces a significantly lesser initial growth rate.

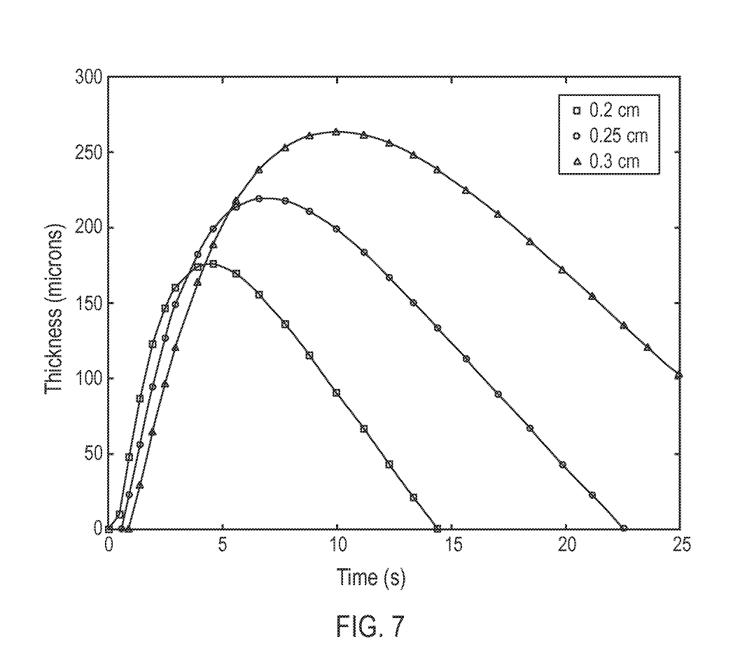

FIG. 7 shows an graphical representation of an exemplary theoretical calculation illustrating the maximum thickness of a solidified silicon layer that may be achieved as a function of the mold thickness corresponding to a thickness of 0.2 cm, 0.25 cm, and 0.3 cm, as illustrated by squares, circles, and triangles, respectively. In the calculations, it was assumed that the mold is made of 100% dense (i.e., nonporous) vitreous silica, that the temperature of the mold core was 100° C. and the external surface was 1300° C. at the time of immersion, and that the molten silicon is maintained at 1470° C. during immersion of the mold in the molten silicon. As shown in the graph, a thicker mold produces a thicker layer of semiconducting material and a lesser initial growth rate.

In at least one embodiment of the disclosure, the thickness of the resulting solid layer may be controlled by altering the immersion time of the mold in the molten semiconducting material. As discussed above, in at least some embodiments of the processes described herein, the solidified layer initially rapidly grows to a maximum possible thickness and then may thin as the solid semiconducting material remelts back into the bulk molten material, which may be maintained at a predetermined temperature. Without wishing to be limited by theory or exemplary calculations, it is believed that during the initial phase, solidification is initiated at the mold-liquid interface followed by the progression of the solidification front into the liquid (i.e., the molten semiconducting material), thereby leading to growth of a solidification layer of a certain maximum thickness. In the latter phase of the process, it is believed that remelting of the solidified layer takes place and the solid-liquid interface recedes towards the mold. If the mold were left in the molten material, all of the initially frozen layer would remelt as the mold thermally equilibrates with the melt.

According to at least one embodiment, the rate at which the mold is immersed into the molten semiconducting material may range from 1.0 cm/s to 50 cm/s, such as, for example, from 3 cm/s to 10 cm/s. One skilled in the art would recognize that the immersion rate may vary depending on various parameters, such as, for example, the semiconducting material composition (including optional dopants), the size/shape of the mold, and the surface texture of the mold.

In addition to the thickness of semiconducting material contributed by the solidifying/remelting of the semiconducting material over a surface of the mold, the thickness of the formed article of semiconducting material may also be affected by the rate at which mold is withdrawn from molten semiconducting material. Molten semiconducting material may wet the solid layer of semiconducting material formed over the mold as it is withdrawn from molten semiconducting material, forming a drag layer of molten semiconducting material. The drag layer of molten semiconducting material may freeze on the already solidified layer of semiconducting material and thus may add to the thickness of the final article.

A person skilled in the art would recognize that the immersion rate, immersion time, and withdrawal rate may all affect the produced article and that those parameters may be chosen based on the desired article attributes, the material, shape, texture, and size of the mold, the initial temperature of the mold, the temperature of the molten semiconducting material, and the properties of the semiconducting material.

In various exemplary embodiments, the methods of the disclosure may control the nucleation rate of semiconducting material crystals on the mold when making an unsupported article of semiconducting material.

As used herein, the phrase “control the nucleation rate,” and variations thereof, is intended to include any change in the nucleation rate and/or size of the crystalline microstructure of the semiconducting material achieved by the methods disclosed herein relative to methods not within the scope of the disclosure.

For example, as discussed above, elevating the external surface temperature of the mold, T_{Surface}, relative to the temperature of the core of the mold, T_{Mold}, and closer to the temperature of the molten semiconducting material, T_{Melt}, may thereby control the nucleation rate by providing sufficient thermal mass to produce large stable crystals of the semiconducting material and/or prevent excessive nucleation of crystals near the mold surface.

Other various exemplary embodiments, the methods of the disclosure may increase the efficiency of solar cells formed from articles of semiconducting material relative disclosed herein to that of semiconducting materials made by methods other than those disclosed herein.

As used herein, the term “increase the efficiency,” and variations thereof, is intended to mean that the efficiency of solar cells formed from the unsupported article of semiconducting material may be greater than that of solar cells formed from materials made by methods not within the scope of this disclosure. As discussed above, the methods of the disclosure may produce articles of semiconducting material having larger grains of semiconducting material and/or fewer defects than other known methods. In various embodiments, solar cells formed from the unsupported articles of semiconducting material made by the methods disclosed herein may have an efficiency exceeding 13%, such as exceeding 17%.

The methods according to the disclosure may also, in at least some embodiments, yield articles of semiconducting material at an increased rate of production and/or having a reduced material waste.

As used herein, the phrase “increased rate of production” and variations thereof include any increase in the rate of semiconducting material article production relative to conventional methods for producing semiconducting material, such as ribbon growth methods. For example, in at least one embodiment, an increased rate of production may be any rate greater than 1-2 cm/min. In at least one embodiment, immersion cycle times (i.e., the sum of time to immerse the mold, the immersion time, and the time to withdraw the mold) of less than 5 seconds are used to form sheets 7 cm in length (independent of width), which translates to a process speed of a few centimeters per second.

As used herein, the phrase “reduced material waste” and variations thereof mean any reduction in the amount of semiconducting material lost through conventional methods using slicing or cutting following production of the article of semiconducting material. For example, the exocasting processes described herein can be performed with essentially no waste of semiconducting elements because all the melted material can be cast into a useful article. Any broken pieces or other unused material can be remelted and cast again.

Unless otherwise indicated, all numbers used in the specification and claims are to be understood as being modified in all instances by the term “about,” whether or not so stated. It should also be understood that the precise numerical values used in the specification and claims form additional embodiments of the invention. Efforts have been made to ensure the accuracy of the numerical values disclosed herein. Any measured numerical value, however, can inherently contain certain errors resulting from the standard deviation found in its respective measuring technique.

We claim:

1. A method of making an unsupported article of a semiconducting material, comprising:
providing a mold with an external surface temperature T_{surface} and a core temperature T_{core}, whererin T_{surface} >T_{core};
providing a molten semiconducting material at a temperature Tₘₑₗₜ, wherein Tₘₑₗₜ>T_{Core};
immersing the mold in the molten semiconducting material for a period of time sufficient to form a solid layer of the semiconducting material over the external surface of the mold;
withdrawing the mold with the solid layer of semiconducting material from the molten semiconducting material; and
separating the solid layer of semiconducting material from the mold to form the unsupported article of semiconducting material.

2. The method of claim 1, wherein T_{Melt}>T_{Surface}.

3. The method of claim 2, wherein T_{Surface} is about 10° C. to 700° C. less than that of T_{Melt}.

4. The method of claim 1, wherein the semiconducting material is selected from silicon, alloys and compounds of silicon, germanium, alloys and compounds of germanium, gallium arsenide, alloys and compounds of gallium arsenide, tin, alloys and compounds of tin, and mixtures thereof.

5. The method of claim 1, wherein the semiconducting material is selected from silicon, silicon alloys, and silicon compounds.

6. The method of claim 1, wherein T_{Core} is between about 50° C. to 200° C.

7. The method of claim 1, wherein the unsupported article has a thickness ranging from 100 μm to 400 μm.

8. The method of claim 1, wherein the unsupported article further comprises a dopant dispersed throughout the semiconducting material.

9. The method of claim 1, wherein the distance from the core of the mold to the external surface of the mold ranges from about 0.05 cm to 0.5 cm.

10. The method of claim 1, further comprising:
coating the external surface of the mold with particles prior to immersing the mold in the molten semiconducting material and/or as the mold is immersed in the molten semiconducting material.

11. The method of claim 10, wherein the particles are selected from silicon, silicon oxides, silicon nitride, aluminum oxides, aluminum silicate, and combinations thereof.

12. A method of controlling the nucleation rate of crystals of semiconducting material and/or stability of grain growth when making an unsupported article of a semiconducting material during formation of the unsupported article, comprising:
providing a mold with an external surface temperature T_{surface} and a core temperature T_{core}, whererin T_{surface}>T_{core};
providing a molten semiconducting material at a temperature T_{Melt}, wherein Tₘₑₗₜ>T_{Core};
immersing the mold in the molten semiconducting material for a period of time sufficient to form a solid layer of the semiconducting material over the external surface of the mold;
withdrawing the mold with the solid layer of semiconducting material from the molten semiconducting material; and
separating the solid layer of semiconducting material from the mold to form the unsupported article of semiconducting material.

13. The method of claim 12, wherein T_{Melt}>T_{Surface}.

14. A method of increasing the efficiency of a solar cell formed from an article of semiconducting material, comprising:
providing a mold with an external surface temperature T_{surface} and a core temperature T_{core}, whererin T_{surface}>T_{core};
providing a molten semiconducting material at a temperature Tₘₑₗₜ, wherein Tₘₑₗₜ>T_{Core};
immersing the mold in the molten semiconducting material for a period of time sufficient to form a solid layer of the semiconducting material over the external surface of the mold;
withdrawing the mold with the solid layer of semiconducting material from the molten semiconducting material;
separating the solid layer of semiconducting material from the mold to form the unsupported article of semiconducting material; and
forming a solar cell using the unsupported article of semiconducting material.

15. The method of claim 14, wherein T_{Melt}>T_{Surface}.
